(19) United States
(12) Patent Application Publication
(10) Pub. No.: US 2025/0251230 A1
(43) Pub. Date: Aug. 7, 2025

(54) MEASUREMENT PROBE RACK WEIGHT COMPENSATION

(71) Applicant: Hexagon Metrology, Inc., North Kingstown, RI (US)

(72) Inventors: Ingo Lindner, Wetzlar (DE); Milan Kocic, Pawtucket, RI (US)

(21) Appl. No.: 19/045,787

(22) Filed: Feb. 5, 2025

Related U.S. Application Data
(60) Provisional application No. 63/550,505, filed on Feb. 6, 2024.

(51) Int. Cl. G01B 5/012; G01B 21/04; G01R 1/04

(52) U.S. Cl. CPC G01B 5/012; G01B 21/045; G01B 21/047; G01R 1/0416

(57) ABSTRACT

A measurement probe rack weight compensation system for a coordinate measurement machine may include a probe rack including rack ports for storing one or more measurement probes, the probe rack including a plurality of magnetic sensors, each configured to emit a magnetic signal in response to receipt of a magnetic field. The magnetic signal is based on a disposition of measurement probes in the rack ports. The rack ports have a plurality of positional offsets based on a plurality of disposition of measurement probes in the rack ports.

### PRIORITY

This patent application claims priority from U.S. Provisional Patent Application No. 63/550,505, filed Feb. 6, 2024, entitled MEASUREMENT PROBE HEAD COMPENSATION and naming Ingo Lindner, Milan Kocic, and Damien Carron as the inventors, the disclosure of which is incorporated herein in its entirety, by reference. This patent application is also related to U.S. patent application Ser. No. 19/039,175, filed Jan. 28, 2025, entitled MEASUREMENT PROBE HEAD IDENTIFICATION and naming Ingo Lindner and Milan Kocic as the inventors, and U.S. patent application Ser. No. 19/045,735, filed Feb. 5, 2025, entitled MEASUREMENT PROBE HEAD TEMPERATURE COMPENSATION and naming Ingo Lindner and Milan Kocic as the inventors, the disclosure of each of which are incorporated herein in its entirety, by reference.

### FIELD

Illustrative embodiments of the invention generally relate to coordinate measuring machines (CMMs) and, more particularly, various embodiments of the invention relate to weight compensation applied to CMM probe racks.

### BACKGROUND

Coordinate measuring machines (“CMMs”, also known as surface scanning measuring machines) measure geometry and surface profiles or verify the topography of known surfaces. For example, a CMM may measure the topological profile of a propeller to ensure that its surface is appropriately sized and shaped for its specified task (e.g., moving a 24 foot boat at pre-specified speeds through salt water). To that end, conventional CMMs often have a base supporting a workpiece to be measured. The base is directly connected with and supporting a movable assembly having a probe that directly contacts and moves along a surface of a workpiece being measured. CMMs represent a gold standard for accurately measuring a wide variety of different types of workpieces. For example, CMMs can measure critical dimensions of aircraft engine components, surgical tools, and machine parts. Precise and accurate measurements help ensure that their underlying systems, such as an aircraft in the case of aircraft components, operate as specified. Some workpieces are measured to a fine precision, such as on the micron level. The accuracy of a CMM may depend, in part, on the measuring device (e.g., probe/stylus) used for the measurement, where many such probes and stylii may be available.

### SUMMARY OF VARIOUS EMBODIMENTS

In accordance with one embodiment of the invention, a measurement probe rack weight compensation system for a coordinate measurement machine may include a probe rack including rack ports for storing one or more measurement probes, the probe rack including a plurality of magnetic sensors, each configured to emit a magnetic signal in response to receipt of a magnetic field. The magnetic signal is based on a disposition of measurement probes in the rack ports. The rack ports have a plurality of positional offsets based on a plurality of disposition of measurement probes in the rack ports.

In accordance with other embodiments, the system may include a reader, configured to receive the magnetic signals and convert the magnetic signals into magnetic signatures. The reader is further configured to determine a positional offset of the rack ports as a function of the magnetic signatures, where the determined positional offset is one of the plurality of positional offsets.

In accordance with other embodiments, the reader may include a coil to detect each magnetic signal.

In accordance with other embodiments, the plurality of magnetic sensors are located on different portions of probe rack members, where at least one probe rack member includes the rack ports and positionally deflects based on the disposition of the measurement probes.

In accordance with other embodiments, the reader may include a passive portion configured to receive the magnetic signals and an active portion configured to emit the magnetic field toward the magnetic sensor.

In accordance with other embodiments, the active portion uses magnetic induction to produce the magnetic signal received by the passive portion.

In accordance with other embodiments, the reader may include a memory device, configured to store the plurality of positional offsets cross referenced to the magnetic signatures for different dispositions of measurement probes within the probe rack, where each of the positional offsets corresponds to magnetic signatures at a different disposition of the measurement probes and a processor, coupled to the memory device. In accordance with other embodiments, the processor is configured to determine a positional offset for the magnetic signatures based on the disposition of measurement probes.

In accordance with other embodiments, the processor communicates the positional offset to the coordinate measurement machine, and in response the coordinate measurement machine adjusts a target position of a rack port by the positional offset.

In accordance with other embodiments, the current positional offset may include one or more of an x-axis, a y-axis, and a z-axis amount.

In accordance with another embodiment of the invention, a method of determining a probe rack weight compensation offset for a coordinate measurement machine may include receiving, by a plurality of magnetic sensors associated with a probe rack, a magnetic field, and emitting, by the plurality of magnetic sensors, magnetic signals based on the magnetic field and a disposition of measurement probes in rack ports, the rack ports having a plurality of positional offsets based on a plurality of dispositions of measurement probes in the rack ports. The probe rack may include rack ports for storing measurement probes.

In accordance with another embodiment of the invention, a computer program product for use on a computer system for a probe rack weight compensation offset for a coordinate measurement machine, the computer program product including a tangible, non-transient computer usable medium having computer readable program code thereon. The computer readable program code may include program code for causing emission of a magnetic field toward a magnetic sensor of a probe rack to cause the magnetic sensor to produce a magnetic signal and program code for converting the magnetic signal into a positional offset, the rack ports having a plurality of positional offsets based on a plurality of dispositions of measurement probes in the rack ports. The probe rack includes rack ports for storing the measurement probes.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1A schematically shows a diagram illustrating a representative coordinate measurement machine (CMM) in accordance with illustrative embodiments.

FIG. 1B schematically shows an interface panel that may be used with the coordinate measuring machine in accordance with illustrative embodiments.

FIG. 2 schematically shows a probe rack diagram in accordance with illustrative embodiments.

FIG. 3 schematically shows a detachable probe in accordance with illustrative embodiments.

FIG. 4 schematically shows a stylus rack in accordance with illustrative embodiments.

FIG. 5 schematically shows a stylus in accordance with illustrative embodiments.

FIG. 6 schematically shows a CMM measurement process in accordance with illustrative embodiments.

FIG. 7 schematically shows a sensor system in accordance with illustrative embodiments.

FIG. 8A schematically shows a sensor disposition for a probe rack in accordance with illustrative embodiments.

FIG. 8B schematically shows horizontal member deflection for a probe rack in accordance with illustrative embodiments.

FIG. 9 shows a rack port compensation table in accordance with illustrative embodiments.

FIG. 10 shows a block diagram of an exemplary rack port weight compensation system in accordance with illustrative embodiments.

FIG. 11 schematically shows a rack port positional offset determination process in accordance with illustrative embodiments.

### DESCRIPTION OF ILLUSTRATIVE EMBODIMENTS

In illustrative embodiments, a coordinate measuring machine (CMM) may utilize a number of different probes of different types for various measurement tasks involving varied workpieces. The probes may include a number of tactile probes that make physical contact with a workpiece being measured. Tactile probes include a probe body and a removable stylus that includes one or more stylus tips. The stylus may be constructed of a material that may experience minor deflection under various ambient temperatures. Deflections may be significant enough to meaningfully deflect the stylus tip and produce inaccurate measurements of the workpiece. The present invention provides temperature compensation for probes/stylii by providing a sensitive magnetic sensor in the probe body. When a sensor is about to be used, the system obtains a magnetic signature from the stylus that corresponds to the current ambient temperature and determines a deflection of the stylus tip. As the coordinate measurement machine obtains measurements of the workpiece(s), the coordinate measurement machine applies the deflection to the actual measurements, thus producing temperature-compensated workpiece measurements. Details are discussed below.

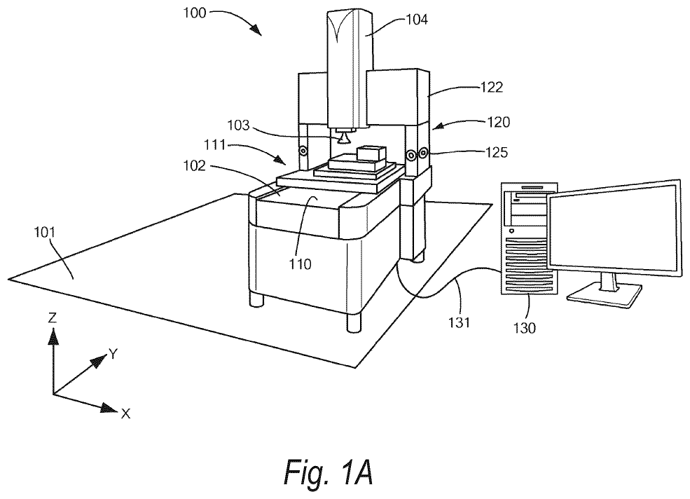

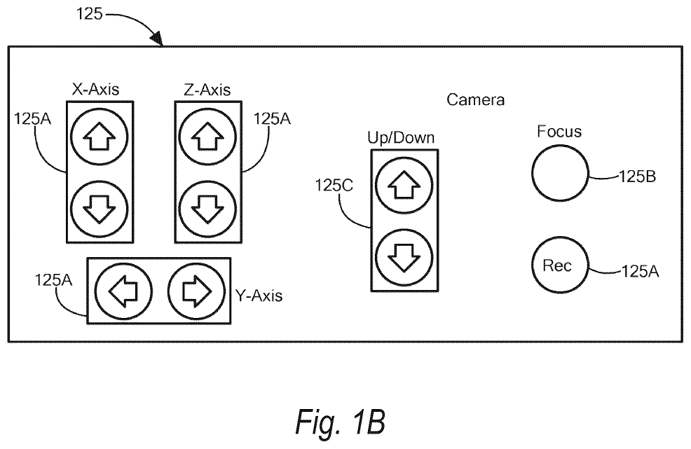

FIG. 1A schematically shows a representative coordinate measurement machine (CMM) 100 in accordance with illustrative embodiments. As known by those of skill in the art, the CMM 100, which is supported on a floor 101 in this illustration, measures a workpiece 111 on its bed/table/base (referred to as “base 102”). Generally, the base 102 of the CMM 100 defines an X-Y plane 110 parallel to the plane of the floor 101.

To measure a workpiece 111 on its base 102, the CMM 100 has movable features 122 arranged to move a measuring device 103, such as a mechanical, tactile probe (e.g., a touch trigger or a scanning probe in a standard CMM 100), a non-contact probe (e.g., using laser probes), and/or a camera (e.g., a machine-vision CMM 100), coupled with a movable arm 104.

Alternately, some embodiments move the base 102 with respect to a stationary measuring device 103. Either way, the movable features 122 of the CMM 100 manipulate the relative positions of the measuring device 103 and the workpiece 111 (or calibration artifact) with respect to one another to obtain the desired measurement. Accordingly, the CMM 100 can measure locations of a variety of features of the workpiece or artifact 111. The CMM 100 has a motion and data control system 120 that controls and coordinates its movements and activities.

Among other things, the control system 120 may include a computing device 130 and the noted sensors/movable features 122. The computing device 130 may include a microprocessor, programmable logic, firmware, advance control, acquisition algorithms, and analysis algorithms. The computing device 130 may have on-board digital memory (e.g., RAM or ROM) for storing data and/or computer code, including instructions for implementing some or all the control system operations and methods. Alternately, or in addition, the computing device 130 may be operably coupled to other digital memory, such as RAM or ROM, or a programmable memory circuit for storing such computer code, measurement data, and/or control data.

Among other things, the computing device 130 may be a desktop computer, a tower computer, or a laptop computer, a tablet computer or a pad computing device, a smart phone, a smart watch, or any other form a wearable computer. The computing device 130 may be coupled to the CMM 100 via a hardwired connection, such as an Ethernet cable 131, or via a wireless link, such as a Bluetooth or a WiFi link. The computing device 130 may, for example, include software to control the CMM 100 during use or calibration, and/or may include software configured to process data acquired during a calibration process (e.g., Hexagon PC-DMIS Pro, PC-DMIS CAD, or PC-DMIS CAD++). In addition, the computing device 130 may include a user interface configured to allow a user to manually operate the CMM 100.

Because their relative positions are determined by the action of the movable features 122, the CMM 100 may be considered as having “knowledge” about data relating to the relative locations of the base 102, and the workpiece or artifact 111, with respect to its measuring device 103. More particularly, the computing device 130 controls and stores information about the motions of the movable features 122. Alternately, or in addition, the movable features 122 of some embodiments may include sensors that sense the locations of the table and/or measuring device 103, and probes, and report that data to the computing device 130. The information about the motions and positions of the table and/or measuring device 103 of the CMM 100 may be recorded in terms of a two-dimensional (e.g., X-Y; X-Z; Y-Z) or three-dimensional (X-Y-Z) coordinate system referenced to a point on the CMM 100. The CMM 100 may also include a user interface 125 that may allow a user to start operation, stop operation, make adjustments, and the like.

FIG. 1B schematically shows a user interface panel that may be used with the coordinate measuring machine, in accordance with illustrative embodiments. As shown, the user interface 125 may have control buttons 125A and knobs 125B that allow a user to manually operate the CMM 100.

Among other things, the user interface 125 may enable the user to change the position of the measuring device 103 or base 102 (e.g., with respect to one another) and to record data describing the position of the measuring device 103 or base 102.

In addition, the user interface 125 may enable the user to focus a camera (if the measuring device 103/arm 104 includes a camera) on a workpiece or target 111 and record data describing the focus of the camera. In a moving table CMM 100, for example, the measuring device 103 may also be movable via control buttons 125C. As such, the movable features 122 may respond to manual control, or under control of the computing device 130, to move the base 102 and/or the measuring device 103 (e.g., a mechanical probe in a mechanical CMM 100 or a camera in a machine vision CMM 100) relative to one another. Accordingly, this arrangement permits the workpiece 111 being measured to be presented to the measuring device 103 from a variety of angles, and in a variety of positions and orientations.

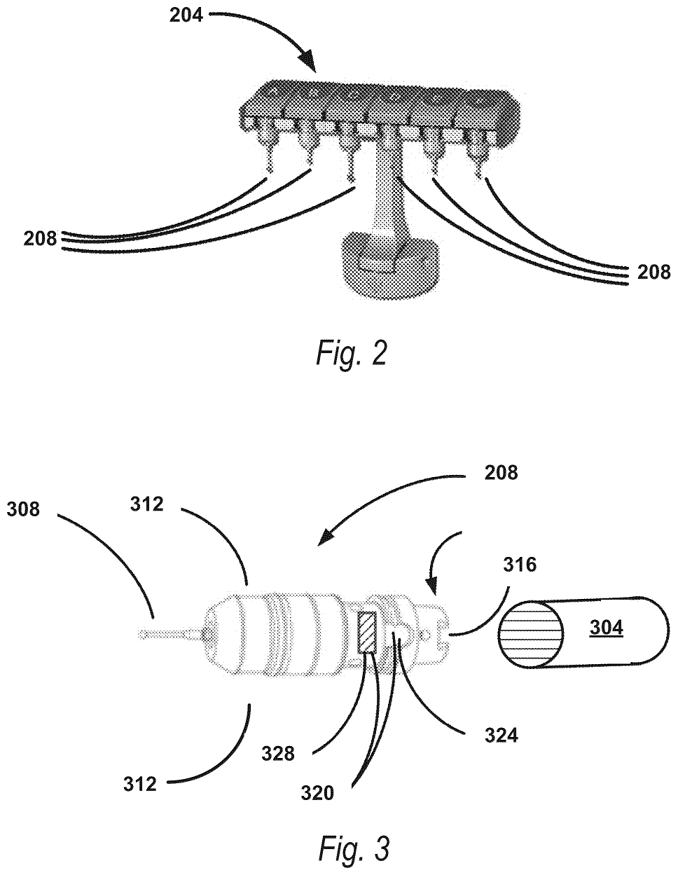

FIG. 2 schematically shows a probe rack 204 in accordance with illustrative embodiments. As shown, the probe rack 204 may store one or more different probes 208 with stylii in general proximity to the CMM 100. That rack may be coupled directly to the CMM 100 or be separate from the CMM 100. Different probes 208 may have different stylus sizes installed or be different types of probes 208. In one embodiment, one or more probes 208 may include multiple stylii. The multiple stylii may have different lengths or physical dimensions or be different types of stylii (e.g., tactile, optical, camera, etc.). The probe rack 204 may provide a uniform way to store the probes 208 in an organized and centralized fashion. Each probe 208 may have its own probe port, and in one embodiment, the probe ports may be equally spaced within the probe rack 204. Each of the probes 208 may be selectively and individually coupled with the movable arm 104 of the CMM 100. As noted above, the probes 208 may be any one of a variety of types of probes 208, such as a mechanical, tactile, or non-contact probe such as an optical probe or camera, to name but a few examples. In operation, any of the probes 208 may be changed, removed from and/or coupled to the movable arm 104 of the CMM 100, either manually by an operator, or robotically by the CMM 100. For example, a probe 208 may be removed from a probe port and coupled to a probe interface 304, as shown in FIG. 3. In one embodiment, probe 208 selection may depend on a workpiece to be measured 111. Although probe rack 204 is shown with a base, one vertical member, and one horizontal member, the present invention applies to any type of probe rack 204 and probe rack 204 members. Probe rack 204 members may be straight, angled, curved, of have complex shapes.

FIG. 3 schematically shows a detachable probe 208 in accordance with illustrative embodiments. Some probes 208 may be configured to operate with a specific type of stylus 308. For example, some probes 208 may have an interface 304 that includes one or more sensors 312 to detect deflection of a tactile stylus 308 when that stylus 308 contacts a workpiece 111. Other probes 208 may have an interface 304 (which may be referred to as a “stylus interface”) that includes electronics to receive electrical signals, such as from an optical stylus or multiple stylii, for example. In one embodiment, the probe 208 may twist onto a distal end of the probe interface 304 and may include one or more retention features.

Probes 208 may also include a probe body 312 with a physical interface 316 (to mount to the CMM 100) having a probe indicium 320 to identify a probe physical feature. They indicium 320 may be in the form of the physical feature that uniquely identifies the probe 208, or its type. The corresponding probe interface 304 on the CMM 100, alone or in concert with the computing device 130, may confirm the identity of the probe 208 by sensing the physical feature through the physical interface 316.

In another embodiment, the body 312 of the probe 208 may have a surface feature 324 that uniquely identifies the probe 208, or its type, and which may be detected by the CMM 100, for example, by using a camera. Among other things, the surface feature 324 may include raised text, a color, or recesses in a specified pattern. In another embodiment, the body 312 of the probe 208 may include an identity interface 328 that uniquely identifies the probe 208, or its type. For example, the identity interface 328 may be an optically readable feature such as a bar code, a color, or another optical indicia that may be read by the camera. In other embodiments, the physical interface 316 may be an electrical interface configured to make electrical contact with the CMM 100 and generate an electrical signal with a pattern or signature that uniquely identifies the probe 208. For example, this interface 316 may be a part of the probe interface 304 that couples with the CMM arm 104. In other embodiments, the physical interface 316 may include a transmitter, such as an RFID chip, that transmits an identifier that uniquely identifies the probe 208, for example in response to a query from the CMM 100. In one embodiment, each probe 208 may include a contactless sensor (not shown) within the probe body 312.

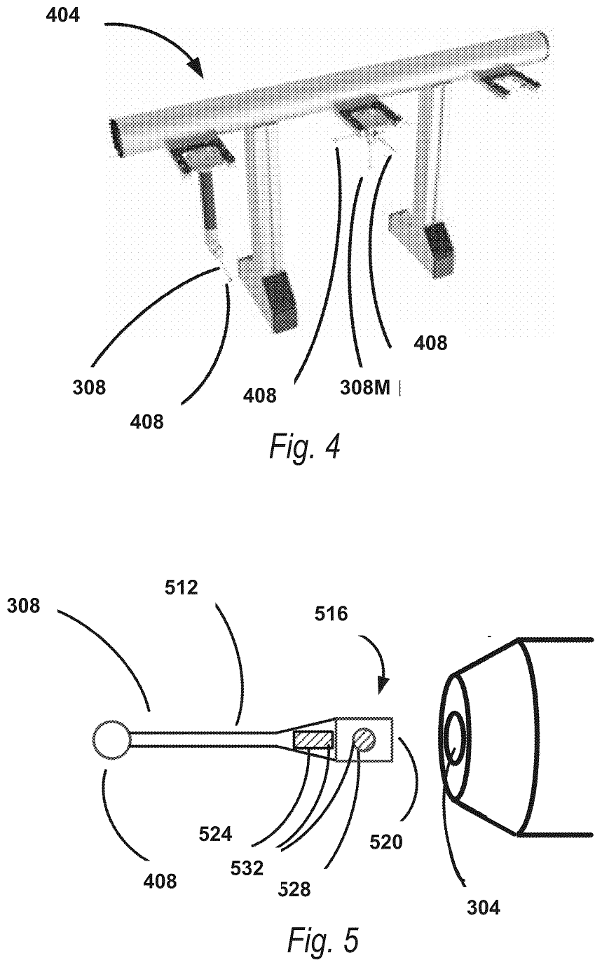

FIG. 4 schematically shows a stylus rack 404 in accordance with illustrative embodiments. Each stylus 308 in the stylus rack 404 may be coupled with a probe 208, and thereby coupled to the movable arm 104 of the CMM 100, and accordingly functions as the above-noted measuring device. Moreover, each stylus 308 may be any one of a variety of types of stylus 308, such as a single-headed stylus 308 having a single stylus tip 408 (e.g., FIG. 5), or a multi-headed-stylus 308M having more than one stylus tip 408, and may be a tactile stylus (e.g., a stylus that measures a workpiece 111 by contacting the workpiece 111), or a non-contact stylus (e.g., a stylus that measures a workpiece 111 without contacting the workpiece 111), to name but a few examples. In operation, a stylus 308/308M may be changed, removed from, and/or coupled to a probe 208, either manually by an operator, or automatically (robotically) by the CMM 100. For example, the stylus 308/308M may be removably coupled to the probe body 312.

FIG. 5 schematically shows another stylus 308 in accordance with illustrative embodiments. As known by those in the art, the stylus 308 includes a body 512 and a stylus tip 408. The stylus 308 mounts to the probe 208 via the probe interface 304 using a physical interface 516. The physical interface 516 may include a physical feature 520 that uniquely identifies the stylus 308. A corresponding stylus interface on the probe 304, alone or in concert with the computing device 130, may confirm an identity of the stylus 308 by sensing the physical feature 520. In one embodiment, a stylus 308 may include a contactless sensor 524. In one embodiment, a stylus 308 may also include one or more forms of indicia 528, 532 other than or in addition to a contactless sensor 524.

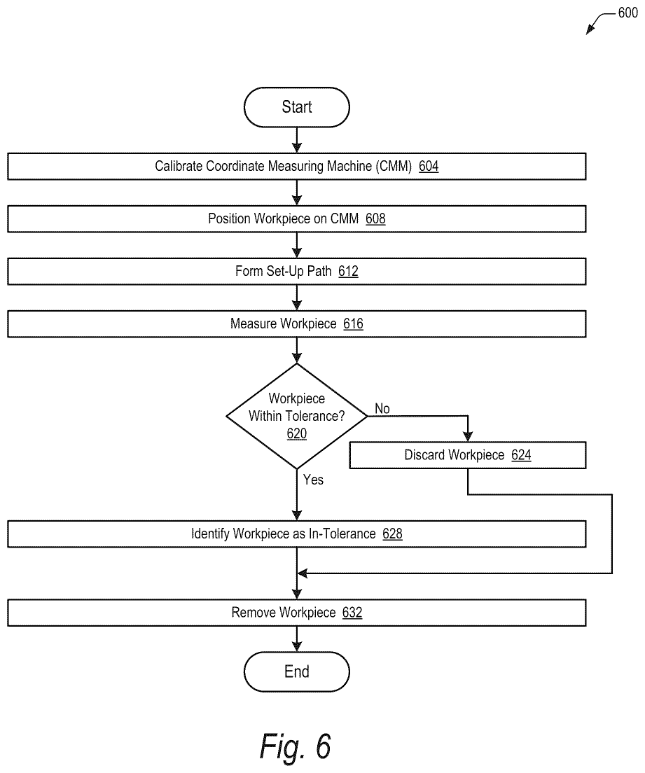

FIG. 6 schematically shows a CMM Measurement Process 600 with a tactile stylus 308. Some of the steps shown in FIG. 6 may be performed in a different order than that shown or at the same time. Those skilled in the art therefore can modify the process as appropriate. It also should be noted that reference to an operator performing certain steps is but one of a number of different options. Some embodiments may use a logic device or automated robot to perform some of the steps. Accordingly, discussion of an operator is not intended to limit various embodiments. This process preferably is repeated many times for a plurality of different workpieces 111 manufactured to a same specification. For example, this process may be used to measure hundreds of jet engine blades that nominally are identically manufactured.

The process of FIG. 6 begins at step 604, in which an operator calibrates the CMM 100. More particularly, to accurately measure the workpiece 111, the CMM 100 should have data relating to the actual orientation and position of an optional rotary table (or on the base without a rotary table) on the CMM 100 relative to the other components of the CMM 100. As such, the system may gather data relating to a vector and a position of the axis about which the rotary table rotates. To that end, an operator first may position a substantially straight shaft at the nominal center of the rotary table. Next, the operator may rotate the shaft in pre-specified increments, such as 90 degree increments, and measure the orientation and location of the shaft at each increment. Using well-known CMM calibration routines, this process should enable the CMM 100 to gather data about the actual orientation and location of the rotary table. In other words, this initial calibration process provides the frame of reference of the rotary table to the system. Flow proceeds to block 608.

At block 608, after calibrating the CMM 100, the operator positions the workpiece 111 on the rotary table of the CMM 100. At this stage of the process, this workpiece 111 just positioned on the rotary table may be the first of a series of nominally identical workpieces 111 to be measured by the CMM 100. Of course, some embodiments may measure just one workpiece 111, or multiple workpieces 111. Flow proceeds to block 612.

At block 612, a set-up or initial path is formed for performing a first scan of the workpiece 111 on the rotary table. More specifically, as known by those skilled in the art, the workpiece 111 preferably was manufactured based on a set of nominal requirements/specifications identifying its ideal structure. For example, the set of nominal requirements may include geometry information, such as the flatness or waviness of the surface, the size of the workpiece 111, the size and shape of certain features of the workpiece 111, the distances between certain features of the workpiece 111, the orientation of certain features relative to other features of the workpiece 111, etc. This set of nominal specifications and/or geometry may be typically stored in a computer-aided design file (a “CAD” file) in a memory device of the CMM 100 (e.g., in memory in the computing device 130). A jet engine blade is a good example of a workpiece 111 that may benefit from illustrative embodiments. As known by those in the art, a jet engine blade has two large, opposed surfaces, and two very thin edges between the two large, opposed surfaces. As also known by those skilled in the art, the two opposed surfaces often have complex contours and geometries that, despite state-of-the-art manufacturing techniques, often widely vary from the nominal requirements. Such workpieces 111 therefore often have relatively large deviations from the nominal.

In one embodiment, the computing device 130 may form the set-up path by using nominal model data present in a computer-aided design (CAD) file, as well as calibration information identifying the position of the rotary table and other parts of the CMM 100.

Because it is based upon nominal information, the set-up path likely may periodically move the workpiece 111 in and out of the focal plane (i.e., beyond the focal length) of the probe 208 during probe travel. Despite that, the set-up path should be accurate enough for the probe 208 to have a first accuracy that is sufficient for its intended function. In other words, although this first accuracy may not be sufficient to appropriately measure the workpiece 111, it should be sufficient to gather data to ultimately form the actual scan path that will be used to measure the workpiece 111. Flow proceeds to block 616.

At block 616, after generating the scan path, the CMM 100 measures the workpiece 111. To that end, the computing device 130 directs the probe 208 along the calculated scan path(s) to determine the actual measurements of prescribed portions of the workpiece 111. Regardless of whether the workpiece 111 has a discontinuity or not, the CMM 100 may measure some or all of each scan path. In some embodiments, the CMM 100 may measure a same or different part of the workpiece 111 with different stylii of a multi-stylus probe 208. This measurement has a second accuracy that preferably is better than the accuracy of the first scan. Flow proceeds to decision block 620.

It should be noted that some embodiments skip this two-pass method to form the scan path. In that case, the measurement platform uses CAD data of the workpiece 111 and other information to set up a path for a full scan.

At decision block 620, the computing device 130 may compare the measured values to the stored nominal measurements and their permitted tolerances. For example, the distance between two prescribed features on side 1 of the workpiece 111 may nominally be 15 millimeters with a tolerance of 0.5 millimeters. Accordingly, the computing device 130 may determine if the measurements of the workpiece 111 are within tolerances specified by the CAD file. Continuing the immediately prior example, if the distance between the two noted features is 15.6 millimeters, then the workpiece 111 is outside of the permitted tolerances. In that case, flow proceeds to block 624. Conversely, if the workpiece 111 is within specified tolerances (e.g., 15.18 millimeters between the two noted features), then flow proceeds to block 628.

At block 624, the workpiece 111 is not within specified tolerances and the computing device 130 may discard the workpiece 111 and/or note the measurement discrepancy. Flow proceeds to block 632.

At block 628, the computing device 130 identifies the workpiece 111 as being within specified tolerances. Flow proceeds to block 632.

At block 632, an operator or other entity may remove the workpiece 111 from the CMM 100. Flow ends at block 632.

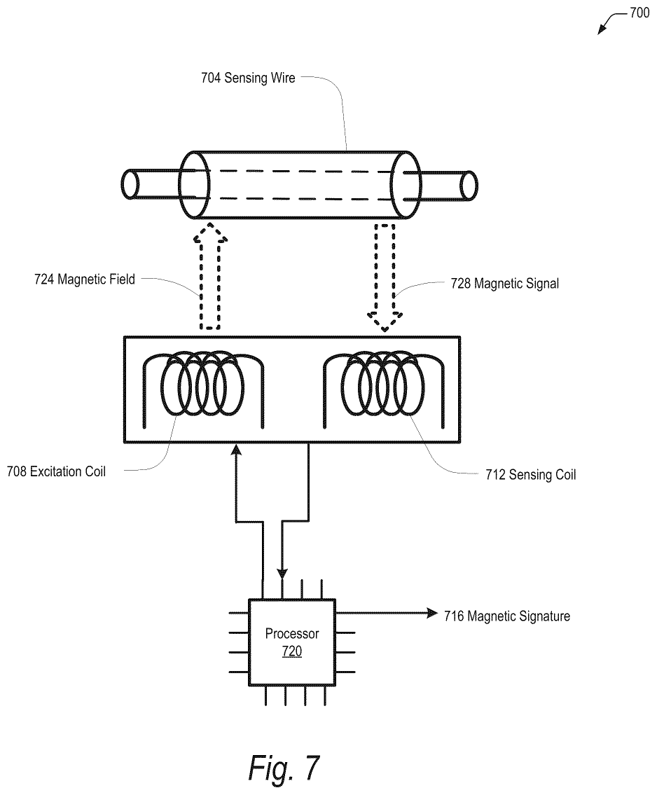

FIG. 7 schematically shows a sensor system 700 that may be used in illustrative embodiments. In one embodiment, a sensor system 700 may include one or more probe racks 204, 404 that each include one or more sensing wires 704, or magnetic sensors, and a reader. The reader may include a passive portion and an active portion. The passive portion may include a sensing coil 712 that receives a magnetic signal 728 via magnetic induction and the active portion may include an excitation coil 708 that emits a magnetic field 724 to the sensing wire 704. The sensing wire 704 may be made from a metallic alloy core surrounded by an insulator.

Other embodiments may use other devices in lieu of the sensing wire 704. For example, some embodiments may use a permanent magnet, magnetostrictive materials (e.g., using Terfenol-D or Galfenol), other piezomagnetic materials that change their magnetic properties (e.g., magnetization or permeability) when subjected to mechanical stress, magnetic markers, encoded tags, inductive devices with permanent magnets.

In the embodiment shown, the excitation coil 708 and the sensing wire 704 are placed proximate to each other, preferably in a mutual position with an asymmetric magnetic field with respect to the sensing wire 704. For example, depending on the specific sensor chosen, a proximity of between 50-100 mm may be required for reliable detection. Unless present in noisy magnetic or electric fields, the excitation coil 708 may be powered with only a few milliamps. Output from the sensing coil 712 may include magnetic and electrical noise present in the vicinity of the sensing coil 712 during measurement. A processor 720 may filter noise from the received signal, level shift the signal, and amplify the signal, if needed.

In one embodiment involving only a single processor 720, the processor 720 or another circuit may provide an AC waveform to the excitation coil 708. The sensing wire 704 is within the proximity of the excitation coil 708 such that the sensing wire 704 reacts according to the magnetic field 724 produced by the excitation coil 708. This magnetic field 724 corresponds to the AC waveform. The sensing coil 712 responsively detects the reaction of the sensing wire 704 and provides a magnetic signal 728 to the processor 720. The processor 720 may then digitize the signal as well as filter/amplify and/or level shift the magnetic signal 728. Based on the relationship between the AC waveform and the received magnetic signal 728, the processor 720 may determine an amount of probe rack 204, 404 deflection associated with a probe rack 204, 404.

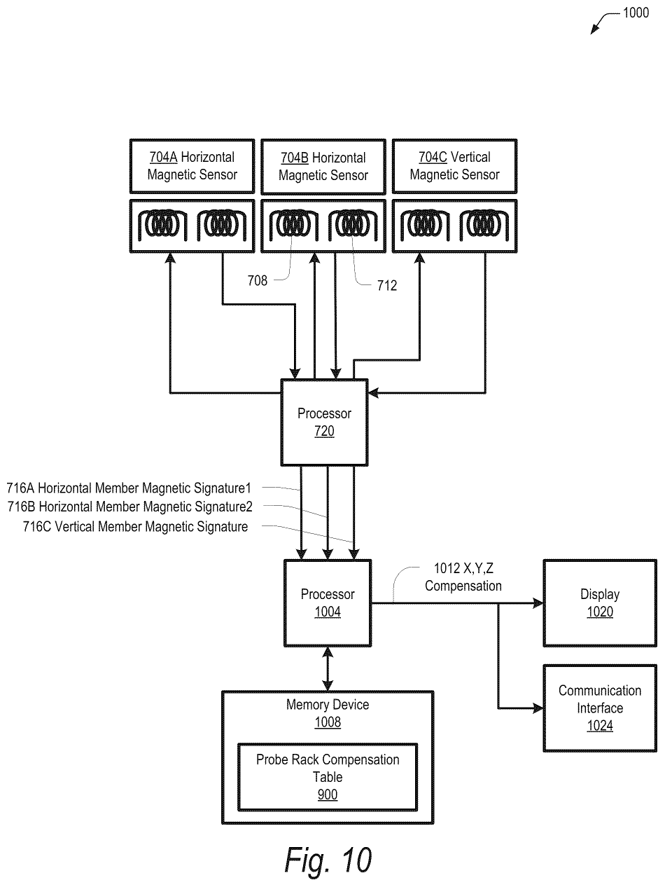

In the illustrated embodiment reflecting the processor 720 and another processor 1004 (FIG. 10), the processor 720 may provide a number of magnetic signatures 716 to further logic or circuitry coupled to a memory device that stores magnetic signatures 716 for multiple magnetic sensors 704. In one embodiment, the coils 708, 712 and possibly the processor 720 may be located where a power source may be available, such as a probe rack port or within CMM robotics 104.

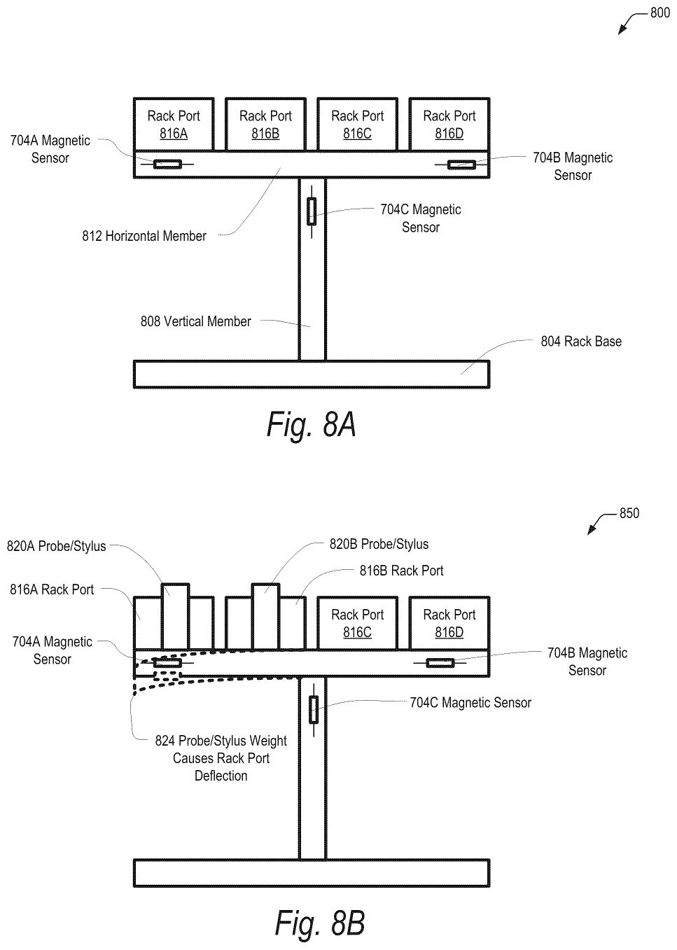

FIG. 8A schematically shows a sensor disposition for a probe rack 800 in accordance with illustrative embodiments. The illustrated probe rack is similar to the two-member probe rack 204 shown in FIG. 2. The illustrated probe rack 800 may include four rack ports 816 for housing probes 208 or probes/stylii 820, identified as rack ports 816A-816D. The rack ports 816A-816D may or may not contain a probe 208 or probe/stylus 820 combination. The rack ports 816 are coupled to a horizontal member 812, which is centrally coupled to a vertical member 808. A rack base 804 supports the vertical member 808. In one embodiment, the vertical member 808 may have a magnetic sensor 704C attached to an end that attaches to the horizontal member 812. This end of the vertical member 808 is not attached to the rack base 804 and may therefore experience minor positional displacement with weight changes from probes/stylii 820 docked to rack port(s) 816.

In one embodiment, the horizontal member 812 may have a passive sensor 704A, 704B located at each end. The ends of the horizontal member 812 may experience positional displacement away from the coupling point to the vertical member 808.

FIG. 8B schematically shows a horizontal member deflection for a probe rack 850 in accordance with illustrative embodiments. The illustrated probe rack is similar to the probe rack 204 shown in FIG. 2, with a horizontal member 812 having left and right portions extending away from a central member 808.

FIG. 8B illustrates a similar arrangement as probe rack 800 in FIG. 8A. However, probe rack 816A now includes probe/stylus 820A, probe rack 816B now includes probe/stylus 820B, and rack ports 816C and 816D are empty (no probe/stylus 820 docked). Each probe/stylus 820 contributes weight to the probe rack horizontal member(s) 812, which may deflect the probe rack 824, especially toward the ends of the horizontal member 812. Each probe/stylus 820 may have a weight that adds a bending moment to the horizontal member 812, where the bending moment is greater the further the probe/stylus is located away from the supporting cross member (i.e., vertical member 808).

FIG. 8B illustrates a single magnetic sensor 704 at each end of the horizontal member 812. In other embodiments, each rack port 816 may have a separate magnetic sensor 704 in close proximity. This may beneficially provide a more accurate deflection reading because it is more closely correlated with a specific rack port 816 location. Because rack ports 816C and 816D do not have a probe/stylus 820 docked, the deflection as measured by magnetic sensor 704B may be zero or a default level. In general, the more probes/stylii 820 docked to rack ports 816 on one side of a cross member, the greater the horizontal member deflection 824 will be.

Different probe/stylii 820 may have different weights due to the type of probe 208 and the complexity/size of an installed stylus 308. Using the configuration shown in FIG. 8B, a heavier probe/stylus 820 may result in greater deflection 824 of the horizontal member 812 when docked to rack port 816A rather than rack port 816B. This is due to a greater bending moment due to a distance from the intersection of the vertical member 808 and the horizontal member 812. Rack port 816A therefore would have a greater contribution to horizontal member deflection 824 than rack port 816B. For these reasons, the arrangement or disposition of measurement probes (i.e., probes/stylii 820) within specific rack ports 816 determines the amount of probe rack 204, 404 deflection, and therefore rack port 816 deflection. Therefore, the current disposition of measurement probes (208, 820) in rack ports 816 determines the current positional offset the CMM 100 needs to apply to a default rack port 816 location to reliably store or retrieve a measurement probe 208, 820).

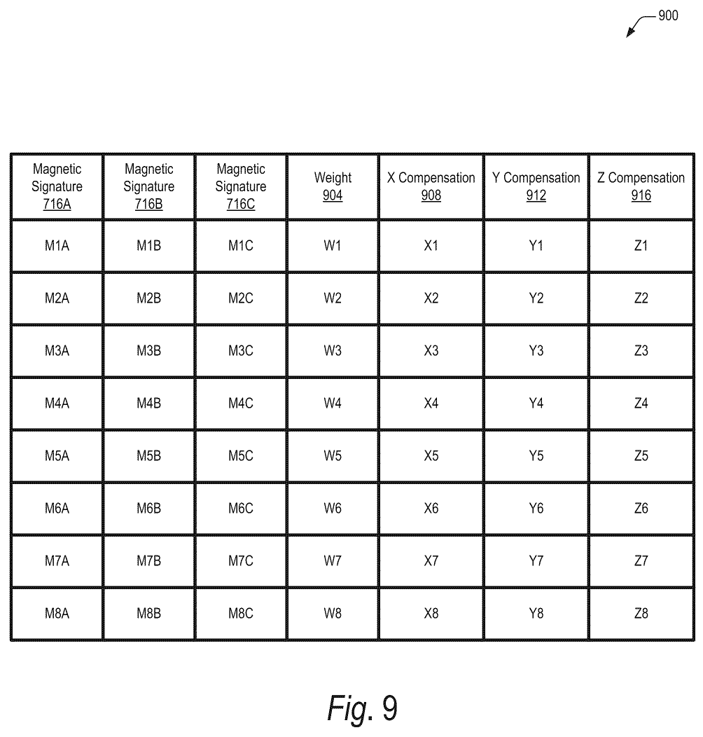

FIG. 9 shows a rack port compensation table 900 in accordance with illustrative embodiments. Each individual probe rack 204, 404, horizontal member 812 section, or probe/stylus rack port 816 used with a CMM 100 would preferably have its own rack port compensation table 900 prior to accessing a rack port 816 to either store a probe/stylus 820 or retrieve a new probe/stylus 820. FIG. 9 reflects an example of a rack port compensation table 900 for a probe rack 204 similar to that shown in FIG. 8A with three magnetic sensors 704A, 704B, and 704C. Other rack port compensation tables 900 may be created and utilized for a lesser or greater number of magnetic sensors 704 in a probe rack 204, 404, although in most embodiments, at least three magnetic sensors 704 may be present.

The CMM system 100 initially records an x, y, z location in some coordinate system for a default location in space for each rack port 816 in each probe rack 204, 404. The default location may be a center, a corner, or any other discrete point of a rack port 816. The default location may be used by the CMM 100 to guide a robotic actuator or movable arm 104 to a rack port 816 to reliably and safely dock or obtain a probe/stylus 820. The default location may be modified by the system described herein based on current weight and disposition of probes/stylii 820 in the probe rack 204, 404. The coordinate system may be measured from a static point on the CMM 100 (e.g., a point on the base 102) rather than a room the CMM 100 is installed in case the CMM 100 moves during use.

Rack port compensation table 900 may be generated by successively testing the probe rack 204, 404 at a range of weights 904 (i.e., permutations of probe/stylus 820 and rack port 816 combinations). Initial testing will determine the sensitivity of the probe rack 204, 404 members (and more specifically rack port 816 coordinates) to weight changes. This and the range of probe/stylus 820 weights for the CMM 100 will establish the number of rows in the table 900 and the difference in weight 904 between each pair of rows (i.e., weight increments). The idea is to utilize a weight 904 granularity or increment where a noticeable x, y, and/or z offset starts to occur. Once a new rack port compensation table 900 is completed for a probe rack 204, 404, it is available to be used for probe rack 204, 404 weight compensation. A minimum weight is when no probes/stylii 820 are docked in any rack ports 816. Therefore, weight W1 904 may have corresponding X1, Y1, and Z1 values that reflect no weight compensation.

A rack port compensation table 900 may include entries based on magnetic signatures 716. For example, referring to FIG. 8A, magnetic sensor 704A may produce magnetic signature 716A, magnetic sensor 704B may produce magnetic signature 716B, and magnetic sensor 704C may produce magnetic signature 716C. The number of entries may not be fixed between different rack port compensation tables 900 since weight granularity may affect probe racks 204, 404 and rack ports 816 differently. For example, a first probe rack 204A may not experience a noticeable deflection based on weight at 1 ounce (oz) difference while a second probe rack 204B may experience a noticeable deflection based on weight at 0.5 oz difference. In that case, the rack port compensation table 900 for the second probe rack 204B may have four or more times as many weight entries 904 as the rack port compensation table 900 for the first probe rack 204A.

FIG. 9 illustrates an example with eight weight entries 904, identified as W1-W8. This corresponds to eight magnetic signatures 716 entries, identified as entries M1A-M8A from magnetic sensor 704A, M1B-M8B from magnetic sensor 704B, M1C-M8C from magnetic sensor 704C, eight X compensation 908 entries, identified as X1-X8, eight Y compensation 912 entries, identified as Y1-Y8, and eight Z compensation 916 entries, identified as Z1-Z8. For the example of FIG. 10, eight weight increments W1-W8 may be sufficient if the weight range is from 0-4 kilograms (8.818 lbs) and half kilogram increments is the minimum granularity.

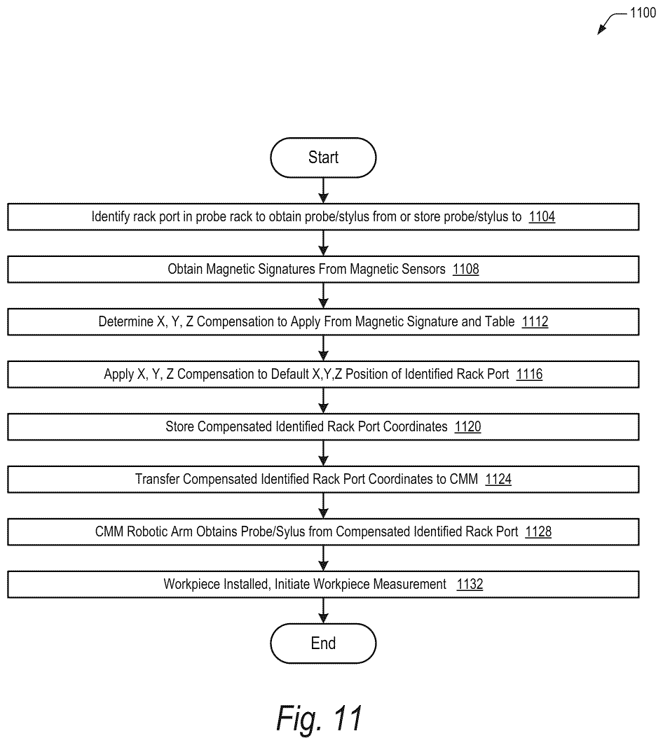

In response to receiving magnetic signatures 716 from each magnetic sensor 704 in a probe rack 204, 404, a processor 720, 1004, 130 identifies the corresponding rack port compensation table 900 in a memory device 1008 and cross references the magnetic signatures 716 to find the corresponding X 908, Y 912, and Z 916 compensations for the weight 904 (which corresponds to the magnetic signatures 716). This is explained more with reference to FIGS. 10 and 11.

FIG. 10 shows a block diagram of an exemplary rack port weight compensation system 1000 in accordance with illustrative embodiments. A CMM 100 may include a number of probe racks 204, 404 including rack ports 816 to store a variety of different types and sizes of probes/stylii 820. For example, FIG. 10 illustrates three magnetic sensors 704A, 704B, and 704C associated with a probe rack 204 such as probe rack 800 shown in FIG. 8A.

Associated with each magnetic sensor 704 is a reader that may include an active sensor portion that includes an excitation coil 708 and a passive sensor portion that includes a sensing coil 712, as shown in FIG. 7. Each input and output to/from the coils 708, 712 is provided to the processor 720. As stated with respect to FIG. 7, the processor 720 may generate AC waveforms to the excitation coils 708 and filter noise, level shift and/or amplify the signal, and digitize inputs from the sensing coils 712.

In one embodiment (not shown), the same processor 720 may interface with the coils 708, 712 as well as one or more memory devices 1008, communication devices 1024, and/or display devices 1020. In the illustrated embodiment, the processor 720 may provide the digitized magnetic signatures 716 corresponding to each magnetic sensor 704 to another processor 1004 that interfaces with a memory device 1008, a display 1020 (and possibly a communication device 1024 to transmit unique weight compensations 1012 to the CMM 100 or other entity). A first magnetic signature 716A for a horizontal member 812, a second magnetic signature 716B for the horizontal member 812, and a magnetic signature 716C for a vertical member 808 (as shown in FIG. 8A) may be provided to processor 1004.

In response to the processor 720 generating magnetic signatures 716 or changes to magnetic signatures 716, the processor 1004 may read a rack port compensation table 900 stored in an accessible memory device 1008 to determine a unique weight compensation 1012 and transmit the unique weight compensation 1012 to a display 1020 and/or a communication device 1024. A weight compensation 1012 may include an X compensation 908, a Y compensation 912, and a Z compensation 916 based on the received magnetic signatures 716 A, 716B, and 716C.

FIG. 11 schematically shows a rack port positional offset determination process 1100 in accordance with illustrative embodiments. Before a workpiece 111 can be measured, a probe/stylus 820 to be used for the next measurements is obtained from a rack port 816 of a selected probe rack 204, 404. In some embodiments, a movable arm 104 of the CMM 100 may first need to dock a currently attached probe/stylus 820 to an empty rack port 816 (i.e., a rack port 816 that is not currently docked with a probe/stylus 820) before obtaining a new probe/stylus 820 from a different rack port 816. Rack port 816 positions/coordinates drift according to weight changes to the probe rack 204, 404. In order for the robotic arm 104 and probe interface 304 of the CMM to reliably grasp a probe/stylus 820 from a rack port 816 or dock a probe-stylus 820 to the rack port 816, the positional offsets 1012 for the probe rack 204, 404 and rack port 816 must be determined and applied to a default position/coordinates for the proper rack port 816 (i.e., the rack port 816 containing the proper probe/stylus 820 to use for the next workpiece 111 measurements or the empty rack port 916 that a current probe/stylus 820 is to be returned to).

The process begins at block 1104, where the proper rack port 816 in the probe rack 204, 404 is identified. The proper rack port 816 provides temporary storage for a probe/stylus 820 to be used for next workpiece 111 measurements or an empty rack port 816. In one embodiment, the processor 1004 may receive a request from the computing device 130 to access a specified probe/stylus 820 in a specific rack port 816. This may cause the processor 1004 to determine a positional offset 1012 (X, Y, Z compensation 1012) for the rack port 816 and probe rack 204, 404. Flow proceeds to block 1108.

At block 1108, magnetic signatures 716 are obtained from the magnetic sensors 704 of the probe rack 204, 404. In one embodiment, each probe rack 204, 404 may include a number of magnetic sensors 704 on one or more 808 and 812 member(s) of the probe rack 204, 404, as described with reference to FIGS. 8A and 8B. Vertical member(s) 808 are attached to the base 804 of the probe rack 204, 404 and generally extend vertically or diagonally upward to support one or more horizontal member(s) 812. Horizontal member(s) 812 are attached to the upper ends of the vertical member(s) 808 and the rack ports 816 are coupled to the horizontal member(s) 812. In the simplest embodiment, a probe rack 204 may have a single vertical member 808 and a single horizontal member 812. In more sophisticated embodiments, a probe rack 204, 404 may have any number of horizontal members 812, vertical members 808, and rack ports 816. In one embodiment, magnetic signatures 716 may be obtained continuously from the probe rack 204, 404. In another embodiment, magnetic signatures 716 may be obtained from the probe rack 204, 404 in response to a request the processor 1004 receives from the computing device 130 or the CMM 100. In another embodiment, magnetic signatures 716 may be obtained periodically, such as once every minute, to reduce processing load and power. Flow proceeds to block 1112.

At block 1112, the processor 1004 determines X 908, Y 912, and Z 916 compensations to apply from the magnetic signatures 716 in the rack port compensation table 9000, as detailed in FIG. 9. Flow proceeds to block 1116.

At block 1116, the X 908, Y 912, and Z 916 compensations from block 1112 are applied to a default X, Y, and Z position of the rack port 816 identified in block 1104. In one embodiment, the memory device 1008 may include default X, Y, and Z positions for each rack port 816 in the probe rack 204, 404-for example the rack port 816 locations in space when no probes/stylii 820 are docked in the rack ports 816. The processor 1004 may read the default position for the identified rack port 816 and modify (added or subtracted, per the determined X, Y, and Z compensations 1012) the default position by the X 908, Y 912, and Z 916 compensations to obtain compensated identified rack port coordinates. Flow proceeds to block 1120.

At block 1120, the compensated identified rack port coordinates are stored in a memory device 130, 1008 or a database accessible to the CMM system 100. Flow proceeds to block 1124.

At block 1124, the processor 1004 transfers the compensated identified rack port coordinates to the CMM 100. The compensated identified rack port coordinates provide the CMM robotic arm 104 with exact weight-compensated coordinates the probe interface 304 must move to (i.e., a target position), in order to reliably grasp the next probe/stylus 820 from a rack port 816 or dock a probe/stylus 820 to. Flow proceeds to block 1128.

At block 1128, the CMM robotic arm 104 obtains the identified probe/stylus 820 from the compensated and identified probe rack port 816. Flow proceeds to block 1132.

At block 1132, the workpiece 111 is installed and workpiece 111 measurement may begin. Flow ends at block 1132.

Illustrative embodiments discuss a specific magnetic sensor (e.g., that shown in FIG. 7). Illustrative embodiments may apply to other magnetic sensors, such as simple magnets or magnetic security tags. Accordingly, discussion of a specific magnetic sensor is illustrative and not intended to limit various other embodiments.

Various embodiments of the invention may be implemented at least in part in any conventional computer programming language. For example, some embodiments may be implemented in a procedural programming language (e.g., “C”), or in an object oriented programming language (e.g., “C++”). Other embodiments of the invention may be implemented as a pre-configured, stand-alone hardware element and/or as preprogrammed hardware elements (e.g., application specific integrated circuits, FPGAs, and digital signal processors), or other related components.

In an alternative embodiment, the disclosed apparatus and methods (e.g., see the various flow charts described above) may be implemented as a computer program product for use with a computer system. Such implementation may include a series of computer instructions fixed either on a tangible, non-transitory medium, such as a computer readable medium (e.g., a diskette, CD-ROM, ROM, solid state drive, or fixed disk). The series of computer instructions can embody all or part of the functionality previously described herein with respect to the system.

Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies.

Among other ways, such a computer program product may be distributed as a removable medium with accompanying printed or electronic documentation (e.g., shrink rapped software), preloaded with a computer system (e.g., on system ROM or fixed disk), or distributed from a server or electronic bulletin board over the network (e.g., the Internet or World Wide Web). In fact, some embodiments may be implemented in a software-as-a-service model (“SAAS”) or cloud computing model. Of course, some embodiments of the invention may be implemented as a combination of both software (e.g., a computer program product) and hardware. Still other embodiments of the invention are implemented as entirely hardware, or entirely software.

Various embodiments of the invention have been described in fulfillment of the various objectives of the invention. It should be recognized that these embodiments are merely illustrative of the principles of the present invention. Numerous modifications and adaptions thereof will be readily apparent to those skilled in the art without departing from the spirit and scope of the present invention as defined in the following claims.

What is claimed is:

1. A measurement probe rack weight compensation system for a coordinate measurement machine, the system, comprising:
a probe rack comprising rack ports for storing one or more measurement probes and further comprising:
a plurality of magnetic sensors, coupled to the probe rack, each configured to emit a magnetic signal in response to receipt of a magnetic field, the magnetic signal based on a disposition of measurement probes in the rack ports, the rack ports having a plurality of positional offsets based on a plurality of disposition of measurement probes in the rack ports.

2. The measurement probe rack weight compensation system of claim 1, further comprising:
a reader, configured to receive the magnetic signals and convert the magnetic signals into magnetic signatures, the reader further configured to determine a positional offset of the rack ports as a function of the magnetic signatures, the determined positional offset being one of the plurality of positional offsets.

3. The measurement probe rack weight compensation system of claim 2, wherein the reader comprises a coil to detect each magnetic signal.

4. The measurement probe rack weight compensation system of claim 1, wherein the plurality of magnetic sensors are located on different portions of probe rack members, wherein at least one probe rack member includes the rack ports and positionally deflects based on the disposition of the measurement probes.

5. The measurement probe rack weight compensation system of claim 2, wherein the reader comprises:
a passive portion configured to receive the magnetic signals; and
an active portion configured to emit the magnetic field toward the magnetic sensor.

6. The measurement probe rack weight compensation system of claim 5, wherein the active portion uses magnetic induction to produce the magnetic signal received by the passive portion.

7. The measurement probe rack weight compensation system of claim 2, wherein the reader comprises:
a memory device, configured to store the plurality of positional offsets cross referenced to the magnetic signatures for different dispositions of measurement probes within the probe rack, wherein each of the positional offsets corresponds to magnetic signatures at a different disposition of the measurement probes; and
a processor, coupled to the memory device.

8. The measurement probe rack weight compensation system of claim 7, wherein the processor is configured to determine a positional offset for the magnetic signatures based on the disposition of measurement probes.

9. The measurement probe rack weight compensation system of claim 8, wherein the processor communicates the positional offset to the coordinate measurement machine, and in response the coordinate measurement machine adjusts a target position of a rack port by the positional offset.

10. The measurement probe rack weight compensation system of claim 8, wherein the positional offset comprises one or more of an x-axis, a y-axis, and a z-axis amount.

11. A method of determining a probe rack weight compensation offset for a coordinate measurement machine, the method comprising:
receiving, by a plurality of magnetic sensors associated with a probe rack, a magnetic field, the probe rack comprising rack ports for storing measurement probes; and
emitting, by the plurality of magnetic sensors, magnetic signals based on the magnetic field and a disposition of measurement probes in the rack ports, the rack ports having a plurality of positional offsets based on a plurality of dispositions of measurement probes in the rack ports.

12. The method of claim 11, further comprising:
receiving, by a reader, the magnetic signals;
converting, by the reader, the magnetic signals into magnetic signatures; and
determining, by the reader, the positional offset as a function of the magnetic signature.

13. The method of claim 12, further comprising:
adjusting a location of the rack ports by the determined positional offset; and
obtaining, by the coordinate measurement machine, a measurement probe from a rack port from the adjusted location.

14. The method of claim 11, wherein the plurality of magnetic sensors are located on different portions of probe rack members, wherein at least one probe rack member includes the rack ports and positionally deflects based on the disposition of the measurement probes.

15. The method of claim 12, wherein the reader comprises:
a passive portion configured to receive the magnetic signals; and
an active portion configured to emit the magnetic field toward the magnetic sensor.

16. The method of claim 15, wherein the active portion uses magnetic induction to produce the magnetic signal received by the passive portion.

17. The method of claim 12, wherein the reader comprises:
a memory device, configured to store the positional offsets cross referenced to the magnetic signatures for different dispositions of measurement probes within the probe rack, wherein each of the positional offsets corresponds to magnetic signatures at a different disposition of the measurement probes; and
a processor, coupled to the memory device.

18. The method of claim 17, wherein the processor is configured to determine a positional offset for the magnetic signatures at a disposition of measurement probes.

19. The method of claim 18, wherein the positional offset comprises one or more of an x-axis, a y-axis, and a z-axis amount.

20. A computer program product for use on a computer system for determining a probe rack weight compensation offset for a coordinate measurement machine, the computer program product comprising a tangible, non-transient computer usable medium having computer readable program code thereon, the computer readable program code comprising:
program code for causing emission of a magnetic field toward a magnetic sensor of a probe rack to cause the magnetic sensor to produce a magnetic signal, the probe rack comprising rack ports for storing measurement probes; and
program code for converting the magnetic signal into a positional offset, the rack ports having a plurality of positional offsets based on a plurality of dispositions of measurement probes in the rack ports.

21. The computer program product of claim 20, wherein the computer readable program code further comprising:
program code for receiving, by a reader, the magnetic signal;
program code for converting, by the reader, the magnetic signal into a magnetic signature; and
program code for determining, by the reader, the positional offset as a function of the magnetic signature.

22. The computer program product of claim 21, wherein the computer readable program code further comprising:
program code for adjusting a location of a rack port by the determined positional offset; and
program code for obtaining, by the coordinate measurement machine, a measurement probe from the rack port from the adjusted location.
